(19) United States
(12) Patent Application Publication
(10) Pub. No.: US 2018/0204757 A1
(43) Pub. Date: Jul. 19, 2018

(54) PLASMA PROCESSING APPARATUS

(71) Applicant: Tokyo Electron Limited, Tokyo (JP)

(72) Inventor: Akihito FUSHIMI, Miyagi (JP)

(21) Appl. No.: 15/862,994

(22) Filed: Jan. 5, 2018

(30) Foreign Application Priority Data
Jan. 17, 2017 (JP) 2017-006245

(51) Int. Cl. H01L 21/687; H01J 37/32

(52) U.S. Cl. CPC H01L 21/68735; H01J 37/32642; H01J 37/32568; H01J 37/32174

(57) ABSTRACT

A plasma processing apparatus that plasmatizes a gas that is supplied to inside of a chamber by using high-frequency power used for generating a plasma and applies plasma processing to a substrate is provided. The plasma processing apparatus includes a stage in which a first electrode and a second electrode are formed separately, the second electrode being provided around the first electrode, the substrate being placed above the first electrode, a focus ring being provided above the second electrode; a first high-frequency power supply configured to apply to the first electrode first high-frequency power used for mainly drawing an ion in the plasma; and a second high-frequency power supply, provided independently from the first high-frequency power supply, configured to apply to the second electrode second high-frequency power used for mainly drawing an ion in the plasma.

### BACKGROUND OF THE INVENTION

### 1. Field of the Invention

The present invention relates to a plasma processing apparatus.

### 2. Description of the Related Art

Various techniques for improving uniformity of plasma processing is known (refer to, e.g., Patent Documents 1 and 2). For example, Patent Document 1 discloses a technique in which an impedance adjustment circuit is controlled according to a wear amount of a focus ring that is worn at the time of plasma processing, and thus, high-frequency power applied to the focus ring is changed. According to the above, the uniformity of the plasma processing can be improved by controlling a sheath.

Patent Document 2 discloses that a groove is formed in a base that supports a wafer side of a stage and a focus ring side, and that a wafer is placed on the wafer side and a focus ring is provided on the focus ring side.

According to the above, the heat movement is decreased between the wafer placement side of the stage and the focus ring side, and thus, the uniformity of the plasma processing is improved.

### CITATION LIST

### Patent Document

[Patent Document 1] Japanese Unexamined Patent Application Publication No. 2010-186841
[Patent Document 2] Japanese Unexamined Patent Application Publication No. 2014-150104

### SUMMARY OF THE INVENTION

### Technical Problem

However, the stage described in Patent Documents 1 or 2 is not completely separated into the wafer placement side and the focus ring provided side, and has a structure in which the stage is not separated at least at a part.

As a result, there is a case in which it is difficult to achieve uniformity of the plasma processing between the wafer placement side of the stage and the focus ring provided side.

In view of the above problem, it is an object of an aspect of the present invention to improve uniformity of the plasma processing.

### Solution to Problem

In order to solve the above-described problem, according to an aspect of the present invention, a plasma processing apparatus is provided. The plasma processing apparatus that plasmatizes a gas that is supplied to inside of a chamber by using high-frequency power used for generating a plasma, and applies plasma processing to a substrate. The plasma processing apparatus includes a stage in which a first electrode and a second electrode are formed separately, the second electrode being provided around the first electrode, the substrate being placed above the first electrode, a focus ring being provided above the second electrode; a first high-frequency power supply configured to apply to the first electrode first high-frequency power used for mainly drawing an ion in the plasma; and a second high-frequency power supply, provided independently from the first high-frequency power supply, configured to apply to the second electrode second high-frequency power used for mainly drawing an ion in the plasma.

### Advantageous Effects of Invention

According to an aspect of the present invention, the uniformity of the plasma processing can be improved.

### BRIEF DESCRIPTION OF THE DRAWINGS

FIG. 1 is a drawing illustrating an example of a plasma processing apparatus according to an embodiment of the present invention.

FIG. 2 is an enlarged drawing of an example of a stage according to an embodiment of the present invention.

FIG. 3 is drawing illustrating a state of a sheath above the stage.

FIG. 4A and FIG. 4B are enlarged drawings of another example of a stage according to an embodiment of the present invention.

FIG. 5 is a drawing illustrating an example of a multi-contact structure according to an embodiment of the present invention.

### DETAILED DESCRIPTION OF THE PREFERRED EMBODIMENTS

In the following, an embodiment of the present invention will be described while making reference to the drawings.

It should be noted that, in the present specification and the drawings, the same reference numeral is given to identical elements having substantially the same structure, and duplicated descriptions will be omitted.

[Overall Structure of Plasma Processing Apparatus]

First, a plasma processing apparatus 1 according to an embodiment of the present invention will be described while making reference to an example. The plasma processing apparatus 1 includes a chamber 10 made of a conductive material including, for example, aluminum. The chamber 10 is grounded. A stage 12, used for placing a semiconductor wafer (hereinafter, referred to as a “wafer W”) and a focus ring 16, is provided within the chamber 10. The stage 12 is supported by a support 42. It should be noted that the wafer W is an example of a substrate that is a plasma processing target.

The plasma processing apparatus 1 according to the present embodiment is a parallel plate type plasma processing apparatus in which a stage 12, also functioning as a lower electrode, and a gas shower head 40, also functioning as an upper electrode, are disposed facing each other, and a gas is supplied into the chamber 10 from the gas shower head 40.

The stage 12 is separated into a wafer placement side of the center of the stage 12 (hereinafter, referred to as “wafer W side”) and a focus ring 16 side of an outer edge of the stage 12. There is a complete separation between the wafer W side and the focus ring 16 side.

On an upper surface of the wafer W side of the center of the stage 12, an electrostatic chuck 11 is provided for electrostatically adsorbing a wafer W. The electrostatic chuck 11 has a structure in which an adsorbing electrode 11a as a conductive layer is included in a dielectric 15a. The electrostatic chuck 11 is provided in such a way that the electrostatic chuck 11 covers an upper surface of the wafer W side of the center of the stage 12, entirely. It should be noted that an adsorbing electrode may be included in a dielectric 15b for adsorbing the focus ring 16.

On the wafer W side of the stage 12 according to the present embodiment, a disk-shaped first electrode 13 and the electrostatic chuck 11 are provided on the base 12a. On the focus ring 16 side of the stage 12, a ring-shaped second electrode 14 and the dielectric 15b are provided on the base 12a. A wafer W is placed on the electrostatic chuck 11. The focus ring 16 is provided on the dielectric 15b.

The focus ring 16 is arranged so as to surround the outer edge of the wafer W. It should be noted that the base 12a is formed by a dielectric element.

The dielectric 15a and the dielectric 15b are made of, for example, yttria (Y2O3), alumina (Al2O3), or ceramic. The first electrode 13 and the second electrode 14 are formed by a conductive element made of aluminum (Al), titanium (Ti), steel, or stainless. The focus ring 16 is made of silicon or quartz.

A first power supplying apparatus 20 is connected to the first electrode 13. The first power supplying apparatus 20 includes a first high-frequency power supply 21, a third high-frequency power supply 22, and a first direct-current (DC) power supply 25. The first high-frequency power supply 21 supplies first high-frequency power that is high-frequency power LF mainly used for drawing an ion. The third high-frequency power supply 22 supplies third high-frequency power that is high-frequency power HF mainly used for generating a plasma. The first DC power supply 25 supplies a first direct current.

The first high-frequency power supply 21 supplies the first high-frequency power that has a frequency equal to or less than 20 MHz (e.g., 13.56 MHz, etc.,) to the first electrode 13.

The third high-frequency power supply 22 supplies the third high-frequency power that has a, frequency greater than 20 MHz (e.g., 40 MHz, 60 MHz, etc.,) to the first electrode 13. The first DC power supply 25 supplies the first direct current to the first electrode 13.

The first high-frequency power supply 21 is electrically connected to the first electrode 13 via a first matching box 23. The third high-frequency power supply 22 is electrically connected to the first electrode 13 via a third matching box 24. An internal (or output) impedance of the first high-frequency power supply 21 is matched to a load impedance by the first matching box 23. An internal (or output) impedance of the third high-frequency power supply 22 is matched to a load impedance by the third matching box 24.

A second power supplying apparatus 26 is connected to the second electrode 14. The second power supplying apparatus 26 includes a second high-frequency power supply 27, a fourth high-frequency power supply 28, and a second direct-current (DC) power supply 31. The second high-frequency power supply 27 supplies second high-frequency power that is high-frequency power LF mainly used for drawing an ion. The fourth high-frequency power supply 28 supplies fourth high-frequency power that is high-frequency power HF mainly used for generating a plasma. The second DC power supply 31 supplies a second direct current.

The second high-frequency power supply 27 supplies second high-frequency power that has a frequency equal to or less than 20 MHz (e.g., 13.56 MHz, etc.,) to the second electrode 14. The fourth high-frequency power supply 28 supplies the fourth high-frequency power that has a frequency greater than 20 MHz (e.g., 40 MHz, 60 MHz, etc.,) to the second electrode 14. The second DC power supply 31 supplies the second direct current to the second electrode 14.

The second high-frequency power supply 27 is electrically connected to the second electrode 14 via a second matching box 29. The fourth high-frequency power supply 28 is electrically connected to the second electrode 14 via a fourth matching box 30. An internal (or output) impedance of the second high-frequency power supply 27 is matched to a load impedance by the second matching box 29. An internal (or output) impedance of the fourth high-frequency power supply 28 is matched to a load impedance by the fourth matching box 30.

As described above, the stage 12 according to the present embodiment is separated into the wafer W side and the focus ring 16 side. In other words, in the stage 12, the electrostatic chuck 11 and the first electrode 13, above which the wafer W is placed, are formed on the base 12a formed by a dielectric element, separately from the dielectric 15b and the second electrode 14, above which the focus ring 16 is provided, and which are provided surrounding the first electrode 13.

Further, not only with respect to the above, but also with respect to the power supply system for supplying high-frequency power to the stage 12, two systems (a first power supplying apparatus 20 for the wafer W side and a second power supplying apparatus 26 for the focus ring 16 side) are each provided, independently. With the above arrangement, it is possible to perform controlling of the wafer W side's power-supply and controlling of the focus ring 16 side's power-supply, separately and independently.

Inside of the first electrode 13 and the second electrode 14, a coolant flow path 18a and a coolant flow path 18d are formed, respectively. As a coolant, cooling water, etc., for example, is supplied from a chiller unit 19 into the coolant flow path 18a and the coolant flow path 18d. The coolant is circulated by going through a coolant entrance piping 18b and a coolant exit piping 18c. It should be noted that the coolant flow path 18a and the coolant flow path 18d may be each connected to corresponding chiller units and may be enabled to control the temperatures, independently.

A heat-transfer gas supplying source 34 causes a heat-transfer gas such as a helium gas (He), an argon gas (Ar), etc., to go through a gas supplying line 33 and supplies the gas to a back side of the wafer W on the electrostatic chuck 11. With the above arrangement, the temperature of the electrostatic chuck 11 is controlled by the coolant that is circulated through the coolant flow paths 18a and 18d and by the heat-transfer gas supplied to the back side of the wafer W. As a result, it is possible to control the wafer W to be at a predetermined temperature.

A gas shower head 40 is attached to a ceiling of the chamber 10 via a dielectric shield ring 43 that coats the outer edge of the gas shower head 40. The gas shower head 40 may be electrically grounded. Alternatively, the gas shower head 40 may be connected to a variable direct current (DC) power supply (not shown) so that a predetermined direct current (DC) voltage is applied to the gas shower head 40.

In the gas shower head 40, a gas inlet 45 is formed that is used for introducing a gas from a gas supplying source 41. Inside of the gas shower head 40, there are a center side diffusion room 50a and an outer circumference side diffusion room 50b used for diffusing gases introduced from the gas inlet 45.

In the gas shower head 40, many gas supplying holes 55 are formed that are used for supplying gases from the diffusion rooms 50a and 50b into the chamber 10. The gas supplying holes 55 are arranged in such a way that gases can be supplied to between the stage 12 and the gas shower head 40.

With the above arrangement, it is possible to supply a first gas from the outer circumference side of the gas shower head 40, and to supply a second gas, whose gas type or gas rate is different from the first gas, from the center side of the gas shower head 40.

An exhaust apparatus 37 is connected to an exhaust port 36 provided in a bottom of the chamber 10. The exhaust apparatus 37 is used for discharging gases in the chamber 10, and thereby, the inside of the chamber 10 is maintained at a predetermined degree of vacuum.

A gate valve G is provided in a side wall of the chamber 10. The wafer W is carried into the chamber 10 through the gate valve G. After the plasma processing is applied to the wafer W in the chamber 10, the wafer W is carried out of the chamber 10 through the gate valve G.

In the plasma processing apparatus 1, there is a control unit 101 used for controlling an overall operation of the apparatus. The control unit 101 includes a CPU (Central Processing Unit), a ROM (Read Only Memory), and a RAM (Random Access Memory). The CPU applies desired plasma processing to the wafer W according to various recipes stored in a storage area such as a RAM, etc. In the recipes, apparatus control information for each process is described, which includes a process time, a pressure (gas discharging), high-frequency power or voltage, various process gas flow amounts, temperatures inside the chamber (upper electrode temperature, chamber side wall temperature, electrostatic chuck (ESC) temperature, etc.,), etc.

It should be noted that the recipes may be stored in a hard disk or a semiconductor memory, or may be stored in a storage area at a predetermined position in a state where the recipes are stored in a computer readable portable recording medium such as a CD-ROM, DVD, etc.

It should be noted that a groove 17, which is formed between the wafer W side of the stage 12 and the focus ring 16 side, and which separates the wafer W side from the focus ring 16 side, may be a vacuum space, or may be filled with an insulator 9 such as alumina, etc., or a resin. In the case where the groove 17 is filled with an insulator 9 such as alumina, etc., or a resin, the connection of one of or both of, the first direct-current (DC) power supply 25 and the second direct-current (DC) power supply 31 may be omitted.

[Effects]

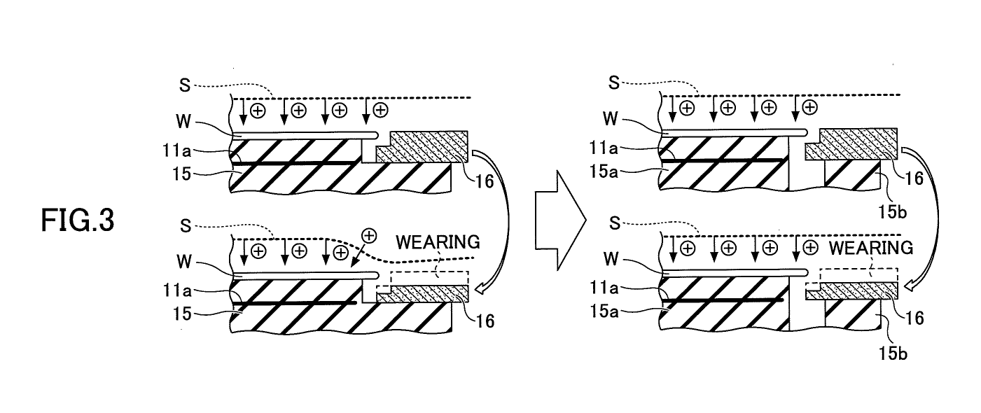

In a plasma processing apparatus 1 according to an embodiment of the present invention, the plasma processing is applied to the wafer W: by generating a plasma by causing a gas supplied from the gas supplying source 41 into the chamber 10 to be ionized or dissociated by using the third high-frequency power HF applied to the stage 12 by the third high-frequency power supply 22 and by using the fourth high-frequency power HF applied to the stage 12 by the fourth high-frequency power supply 28; and by drawing ions in the generated plasma to the wafer W by using the first high-frequency power LF applied to the stage 12 by the first high-frequency power supply 21 and the second high-frequency power LF applied to the stage 12 by the second high-frequency power supply 27. At the time of plasma processing, as illustrated in an upper stage in FIG. 3, a sheath area S is formed above the wafer W and the focus ring 16. Within the sheath area S, mainly ions in the plasma are accelerated toward the wafer W.

The surface of the focus ring 16, which is exposed to the plasma every time the plasma processing is applied, is gradually worn. As a result, as illustrated in the left bottom in FIG. 3, the height of the sheath area S formed above the focus ring 16 becomes lower than that of the sheath area S formed above the wafer W. As a result, in the vicinity of the outermost circumference of the wafer W, the sheath area S is formed in a tilted manner, and thus, in the vicinity of the outermost circumference of the wafer W, an ion enters a hole formed in the wafer W in a tilted manner. As a result, what is termed as “tilting” occurs in which a tilted hole is formed due to the tilted removal by the ion. When the “tilting” occurs, uniformity of the plasma processing is decreased, and thus, it becomes necessary to perform periodic exchange of the focus ring 16 before the “tilting” occurs in order to avoid the decreased yield. However, when a down time is increased due to the shortened exchange period of the focus ring 16, the throughput is decreased and the exchange cost of the focus ring 16 is increased.

Therefore, according to an embodiment of the present embodiment, a structure is provided in which the wafer W side of the stage 12 and the focus ring 16 side are electrically separated, and the power supply control of the wafer W side and the power supply control of the focus ring 16 side are performed separately and independently by using two power supply systems. With the above arrangement, it is possible, for example, to control independently the high-frequency power applied to the focus ring 16 side to be higher than the high-frequency power applied to the wafer W side.

For example, as illustrated in the left side of the lower stage in FIG. 3, in the case where the focus ring 16 is worn, the height of the sheath area S of the focus ring 16 is decreased. In this case, the control unit 101 controls the first high-frequency power supply 21 and the second high-frequency power supply 27 in such a way that the second high-frequency power LF applied to the focus ring 16 side is higher than the first high-frequency power LF applied to the wafer W side. With the above arrangement, as illustrated in the right side of the lower stage in FIG. 3, it is possible to increase the thickness of the sheath area S above the focus ring 16. As a result, as similar to the time before the focus ring 16 has been worn, it is possible to control the height of the sheath area S above the focus ring 16 to be the same as that of the sheath area S above the wafer W. As a result, it is possible to avoid an occurrence of the “tilting” and increase uniformity of the plasma processing, and thus, the decrease in yield can be prevented. Further, it is possible to cause the exchange cycle of the focus ring 16 to be longer, and thus, it is possible to decrease the cost for exchanging the focus ring 16.

[Power Supply Control]

In an embodiment of the present invention, two power supply systems are included, and the two power supply systems are controlled by the control unit 101. The control unit 101 controls the second high-frequency power LF output from the second high-frequency power supply 27 to be relatively higher than the first high-frequency power LF output from the first high-frequency power supply 21. With the above arrangement, it is possible to cause the thickness of the sheath area S formed above the focus ring 16 to be greater than the thickness of the sheath area S formed above the wafer W. As a result, even when the focus ring 16 is worn, it is still possible to control the height of the sheath area S above the focus ring 16 to be the same as that of the sheath area S above the wafer W, and to avoid an occurrence of the “tilting”.

It should be noted that the control unit 101 controls each of the first high-frequency power supply 21 and the second high-frequency power supply 27 independently because the second high-frequency power LF and the first high-frequency power LF contribute mainly to the thickness of the sheath. For example, it is possible to control the thickness of the sheath area S above the focus ring 16 side to be greater than the thickness of the sheath area S above the wafer W side by causing the second high-frequency power applied to the focus ringside to be greater than the first high-frequency power LF applied to the wafer W side.

As an example of a specific control method, the control unit 101 gradually increases the second high-frequency power LF applied to the focus ring 16 side according to the degree of wear of the focus ring 16. As another example of the control method, the focus ring 16 may be made thicker in advance, the control unit 101 may initially control the second high-frequency power LF to be lower than the first high-frequency power LF, and may gradually increase the second high-frequency power LF according to the thickness of the focus ring 16.

The control unit 101 not only applies to the stage 12 the first high-frequency power LF and the second high-frequency power LF for drawing an ion, but also applies to the stage 12 the high-frequency power HF for generating a plasma by controlling at least one of the third high-frequency power supply 22 and the fourth high-frequency power supply 28.

As an example of a specific control method, the control unit 101 may gradually increase the fourth high-frequency power HF applied to the focus ring 16 side according to the degree of wear of the focus ring 16. As another example of the control method, the focus ring 16 may be made thicker in advance, the control unit 101 may initially control the fourth high-frequency power HF to be lower than the third high-frequency power HF, and may gradually increase the fourth high-frequency power HF according to the thickness of the focus ring 16. As described above, it is possible to improve controlling of the thickness of the sheath area S above the focus ring 16 side and the wafer W side by controlling the third high-frequency power HF and the fourth high-frequency power HF in addition to the first high-frequency power LF and the second high-frequency power LF.

It should be noted that, in an embodiment of the present invention, the first high-frequency power supply 21 and the third high-frequency power supply 22 are connected to the wafer W side of the stage 12 and the second high-frequency power supply 27 and the fourth high-frequency power supply 28 are connected to the focus ring 16 side. However, the connections are not limited to the above. For example, the first high-frequency power supply 21 and the third high-frequency power supply 22 may be connected to the wafer W side of the stage 12, and only the second high-frequency power supply 27 may be connected to the focal ring 16 side. Further, for example, only the first high-frequency power supply 21 may be connected to the wafer W side of the stage 12, the second high-frequency power supply 27 and the fourth high-frequency power supply 28 may be connected to the focus ring 16 side, and the third high-frequency power supply 22 may be connected to the gas shower head 40 (upper electrode). Further, for example, only the first high-frequency power supply 21 may be connected to the wafer W side of the stage 12, only the second high-frequency power supply 27 may be connected to the focus ring 16 side, and the third high-frequency power supply 22 may be connected to the gas shower head 40 (upper electrode).

Further, the control unit 101 may apply at least one of the first DC current from the first DC power supply 25 and the second DC current from the second DC power supply 31 to at least one of the wafer W side and the focus ring 16 side of the stage 12. In the structure of the stage 12 according to the present embodiment, the wafer W side of the stage 12 and the focus ring 16 side of the stage 12 are separated from each other, and are separately controlled by using respective power supply systems, and thus, there occurs a potential difference between the first electrode 13 and the second electrode 14. When there occurs a potential difference, there is a case in which there occurs an abnormal discharge in a space inside of the groove 17. Therefore, in order to cause the discharge phenomenon not to tend to occur inside the groove 17, it is preferable that the control unit 101 control at least one of the first DC current and the second DC current so that the potential difference is canceled.

According to the plasma processing apparatus 1 with the above-described structure, it is possible to control the thickness of the sheath area S above the focus ring 16 side and the thickness of the sheath area S above the wafer W side separately by providing two power supply systems, independently, one for the wafer W side of the stage 12 and the other for the focus ring side of the stage 12. With the above arrangement, it is possible to prevent an occurrence of the “tilting”. As a result, it is possible to increase uniformity of the plasma processing.

[Another Power Supply Control]

As an example of another power supply control, the control unit 101 may control the first high-frequency power supply 21 and the second high-frequency power supply 27 in such a way that the second high-frequency power LF applied to the focus ring 16 side is lower than the first high-frequency power LF applied to the wafer W side. With the above control, the thickness of the sheath area S above the focus ring 16 side becomes less than the thickness of the sheath area S above the wafer W side. The above-described control may be used for removing the reaction product adhered to the corner of the outermost circumference of the dielectric 15a of the wafer W side of the center of the stage 12 at the time of wafer-less dry cleaning (WLDC). In other words, at the time of wafer-less dry cleaning (WLDC), the control unit 101 controls the first high-frequency power LF to be lower than the second high-frequency power LF. With the above control, the thickness of the sheath area S above the focus ring 16 side becomes less than the thickness of the sheath area S formed above the dielectric 15a of the wafer W side of the center of the stage 12. As a result, it becomes easier to cause an ion to diagonally attack the corner (shoulder) of the outermost circumference of the stage 12, and thus, it is possible to effectively remove the reaction product adhered to the corner of the outermost circumference of the dielectric 15a of the wafer W side of the center of the stage 12. It should be noted that the control unit 101 may control the first high-frequency power LF to be lower than the second high-frequency power LF, not only at the time of wafer-less dry cleaning, but also at the time of cleaning processes including a dry cleaning performed in a state in which the wafer W is being placed on the stage 12. With the above arrangement, it is possible to perform a cleaning process in which the reaction product deposited at the corner of the outermost circumference of the dielectric 15a of the wafer W side of the center of the stage 12 is removed.

In the above, a high-frequency power LF control process for mainly drawing an ion has been described. However, the control process of the control unit 101 is not limited to the above. The control unit 101 may control the third high-frequency power supply 22 and the fourth high-frequency power supply 28 in such a way that the fourth high-frequency power HF applied to the focus ring 16 side is higher than the third high-frequency power HF applied to the dielectric 15a of the wafer W side. By performing the control process as described above, it becomes possible to cause the plasma density above the focus ring 16 to be higher than the plasma density above the dielectric 15a of the wafer W side of the center of the stage 12, and thus, it becomes possible to, while decreasing the wearing of the dielectric 15a at the time of wafer-less dry cleaning, effectively remove the reaction product adhered to the corner of the outermost circumference of the dielectric 15a of the wafer W side of the center of the stage 12 by using a radical diffused from the plasma above the focus ring 16. At the time of cleaning processes, in addition to the control process for only the high-frequency power LF and the control process for only the high-frequency power HF, a combined control process for the high-frequency power LF and the high-frequency power HF may be performed.

As described above, in the plasma processing apparatus 1 according to an embodiment of the present invention, the stage 12 has a structure in which the stage 12 is separated into the wafer W side and the focus ring 16 side, and two power supply systems are independently provided, one for the wafer W side and the other for the focus ring 16 side. With the above arrangement, it is possible to control the thickness of the sheath area S formed above the focus ring 16 and the thickness of the sheath area S formed above the wafer W side, independently. As a result, it is possible to increase uniformity of the plasma processing.

Further, according to the plasma processing apparatus 1, it is possible to reduce heat interference between the wafer W side of the stage 12 and the focus ring 16 side by having a structure in which the wafer W side of the stage 12 and the focus ring 16 side are separated. With the above arrangement, it is possible to perform temperature control of the stage 12, easily and accurately.

[Temperature Control]

There is a requirement for controlling the temperature of the focus ring 16 at a higher temperature with respect to the temperature of the wafer W in order to improve uniformity of the plasma processing. For example, it is possible to reduce the deposition amount of the reaction product adhered to the focus ring 16 by controlling the temperature of the focus ring 16 side of the stage 12 at a higher temperature with respect to the wafer W side of the stage 12. With the above arrangement, it is possible to reduce an etching rate increase, etc., in the outermost circumference of the wafer W, and thus, it is possible to improve uniformity of the plasma processing.

With respect to the above, it becomes possible to easily control the temperature difference between the wafer W side of the stage 12 and the focus ring 16 side by providing a cooling structure that has two cooling lines in which the cooling lines of the wafer W side of the stage 12 and the focus ring 16 side are independent from each other. However, when two independent cooling lines are provided and a temperature difference is created between the wafer W side of the stage 12 and the focus ring 16 side, a heat exchange is created in an electrical contact surface of the stage 12. Furthermore, in the case where the temperature of the focus ring 16 side of the stage 12 is high, the heat is transferred from the focus ring 16 side of the stage 12 to the wafer W side, the in-plane uniformity of the wafer W is decreased, and the uniformity of the plasma processing is decreased.

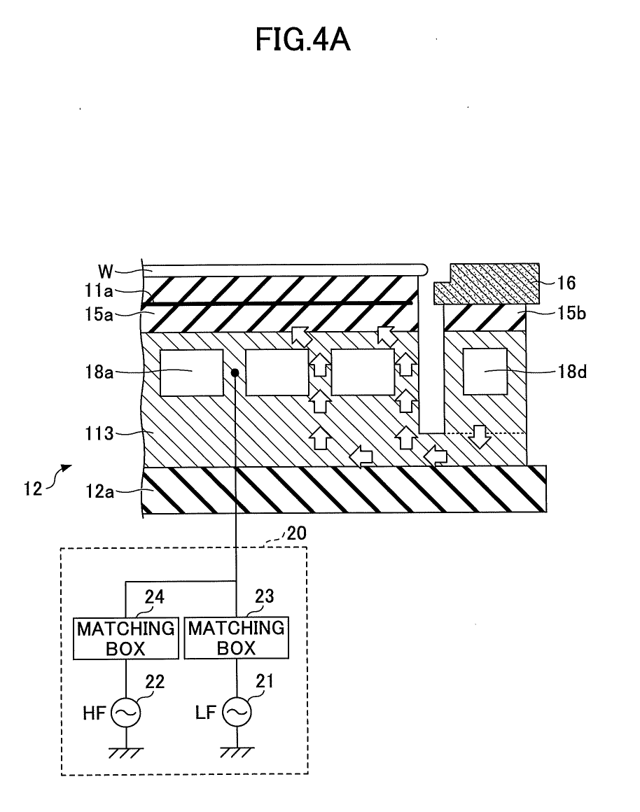

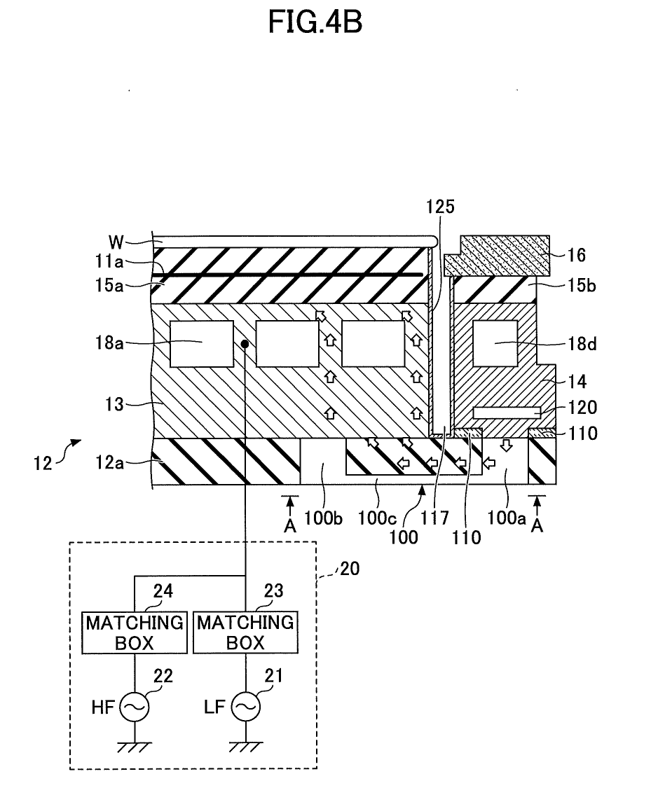

For example, referring to FIG. 4A, a heat exchange will be described in a case in which: there is only one power supply, which is the first power supplying apparatus 20, for applying power to the stage 12; and the wafer W side of the stage 12 and the focus ring 16 side have a structure in which the wafer W side of the stage 12 and the focus ring 16 side are, at least partially, not separated from each other, but are electrically connected to each other via an electrode 113. In the case where there are the two cooling lines, when the control unit 101 controls the temperature of a coolant that flows in the coolant flow path 18d of the focus ring 16 side to be higher than the temperature of a coolant that flows in the coolant flow path 18a of the wafer W side, the heat exchange occurs between the focus ring 16 side and the wafer W side in an electrically connected portion of the electrode 113. In other words, heat is transferred from the focus ring 16 side having a high temperature to the wafer W side of the stage 12 having a lower temperature. With the above operations, the temperature of the outermost circumference side of the wafer W becomes higher than the center side of the wafer W, and thus, uniformity of temperature distribution in the wafer W surface is decreased and uniformity of the plasma processing is decreased.

Therefore, in a plasma processing apparatus 1 according to a modified example of an embodiment of the present invention, as illustrated in FIG. 4B, a structure is provided in which: the wafer W side of the stage 12 does not directly contact the focus ring 16 side while maintaining the electrical connection by a multi-contact element 100; and a dielectric material that has low thermal conductivity is used as a material of the stage 12. With the above arrangement, a structure is provided in which the wafer W side of the stage 12 and the focus ring 16 side are thermally separated. With the above arrangement, the uniformity of temperature distribution in the wafer W surface is increased and the uniformity of the plasma processing is increased.

Specifically, heat exchange between the wafer W side of the stage 12 and the focus ring 16 side is caused not to readily occur by separating the first electrode 13 from the second electrode 14, and by causing the wafer W side of the stage 12 not to contact the focus ring 16 side. In this case, the groove 117, which separates the wafer W side of the stage 12 from the focus ring 16 side, may be a vacuum space, or, as illustrated in FIG. 4B, the groove 117 may be covered with heat insulating material 125. The heat insulating material 125 may be made of resin, silicon, Teflon (registered trademark), or, polymer sheet such as polyimide. Further, the groove 117 may be filled with a dielectric material such as ceramics, etc.

In, any case, it is possible to cause the heat exchange between the wafer W side and the focus ring 16 side of the stage 12 not to readily occur.

Further, in order to form the stage 12 by using a low heat conductivity material, the second electrode 14 may be made of, for example, titanium, steal, stainless, etc., whose heat conductivity is lower than that of aluminum. Further, the second electrode 14 may be made of a material whose heat conductivity is lower than that of the first electrode 13. As an example, a case may be listed in which the first electrode 13 is made of aluminum and the second electrode 14 is made of titanium, etc. With the above arrangement, it is possible to further cause the heat transfer from the focus ring 16 side of the stage 12 to the wafer W side not to readily occur.

Further, a vacuum space 120 may be formed inside of the second electrode 14. With the above arrangement, it is possible to increase heat insulation effects by reducing the heat-transferring cross sections inside of the second electrode 14. The vacuum space 120 may be filled with a dielectric material such as ceramics, etc. Further, in order to increase the heat insulation effects, it is preferable that the vacuum space 120 be provided above the multi-contact element 100 where the heat exchange tends to occur, and that as much space as possible be formed in a radial direction.

Further, a heat insulating material 110 may be included between the second electrode 14 and the base 12a. With the above arrangement, a contact area between the second electrode 14 and the base 12a may be made smaller and the heat transfer between the second electrode 14 and the base 12a may be further reduced. The heat insulating material 110 may be made of resin, silicon, Teflon (registered trademark), or, polymer sheet such as polyimide.

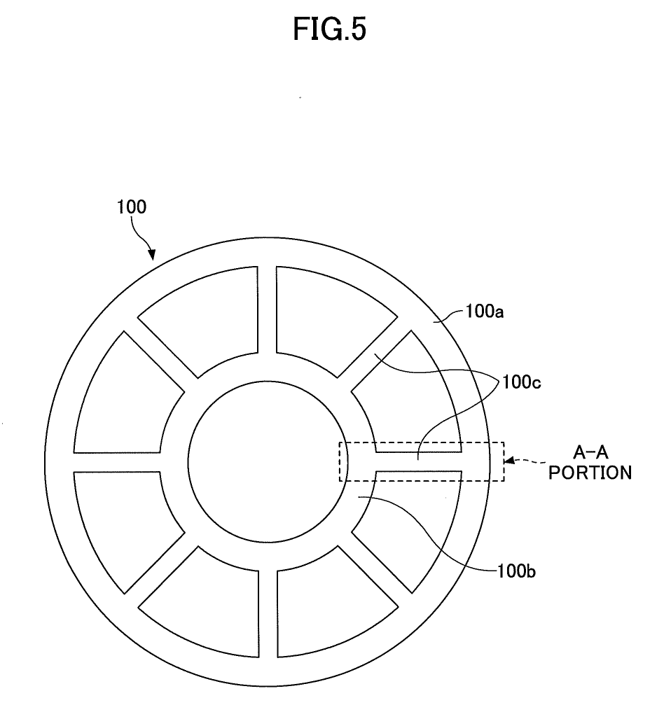

In order to maintain an electrical connection between the wafer W side of the stage 12 and the focus ring 16 side, the multi-contact element 100 is fit in the base 12a such that the first electrode 13 is connected to the second electrode 14. An example of the multi-contact element 100 is illustrated in FIG. 5.

The multi-contact element 100 may be made of metal, and may have a structure in which an outer circumference side ring plate 100a and an inner circumference side ring plate 100b are connected to each other via a metal element 100c. A cross-sectional surface of a part of the multi-contact element 100 is illustrated in FIG. 4B. An A-A portion of the bottom of the multi-contact element 100 in FIG. 4B corresponds to an A-A portion in FIG. 5. The multi-contact element 100 is arranged in such a way that the metal element 100c is arranged evenly in a circumference direction in a state in which the multi-contact element 100 is fit in the base 12a. With the above, arrangement, it is possible to cause the uneven plasma generation not to readily occur.

As described above, in a plasma processing apparatus 1 according to a modified example of an embodiment of the present invention, the wafer W side of the stage 12 and the focus ring 16 side are separated, and the material of the stage 12 is a dielectric material that has low heat conductivity. With the above arrangement, it is possible to cause the heat exchange between the wafer W side of the stage 12 and the focus ring 16 side not to readily occur by having a structure in which the wafer W side of the stage 12 is thermally detached (separated) from the focus ring 16 side.

In addition to the above-described structure, it is possible to accurately control the temperature difference between the wafer W side of the stage 12 and the focus ring 16 side by controlling the cooling line of the wafer W side of the stage 12 and the cooling line of the focus ring 16 side, independently. With the above arrangement, it is possible to increase the in-plane uniformity of temperature distribution in the wafer W, and it is possible to increase the uniformity of the plasma processing.

In addition, in a plasma processing apparatus 1 according to a modified example of an embodiment of the present invention, the electrical connection between the wafer W side of the stage 12 and the focus ring 16 side is secured by the multi-contact element 100. With the above arrangement, it is possible to supply high-frequency power to the wafer W side of the stage 12 and the focus ring 16 side, from a single power supply system.

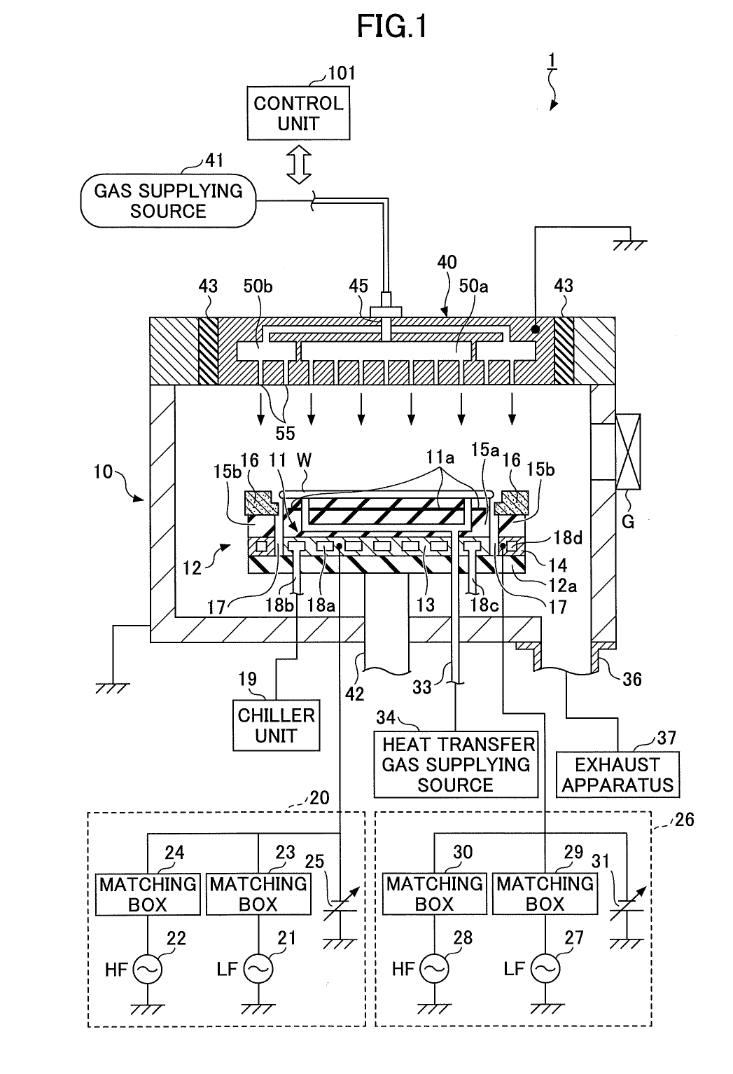

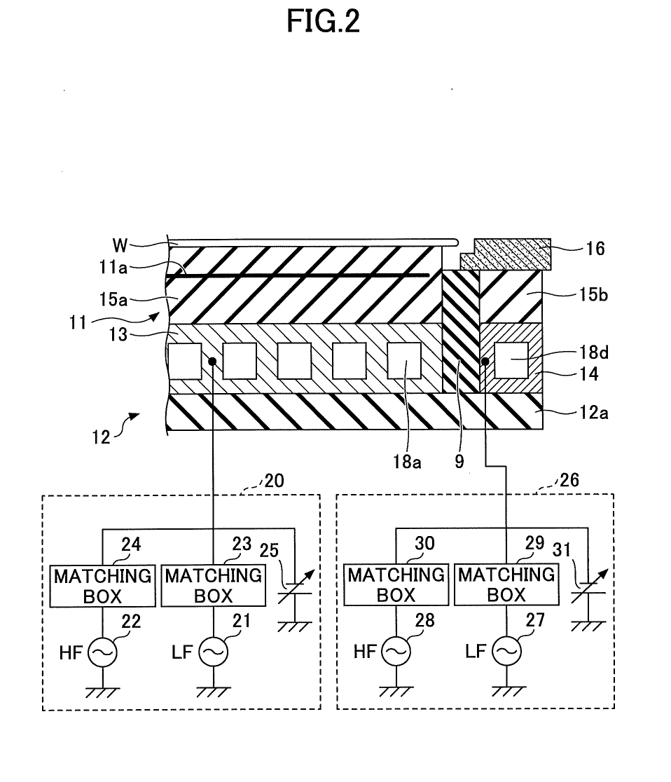

With respect to the above, similar to the plasma processing apparatus 1 according to an embodiment described while making reference to FIG. 1, the plasma processing apparatus 1 may have a structure in which the two power supply systems are included and the multi-contact element 100 is not included. In this case, a structure may be provided in which it is possible to cause the heat exchange between the wafer W side and the focus ring 16 side of the stage 12 not to readily occur.

It should be noted that, in the plasma processing apparatus 1 according to an embodiment described while making reference to FIG. 1, similar to the plasma processing apparatus according to a modified example of an embodiment of the present invention, a structure may be provided in which two cooling line systems are included and the coolant flow path 18a and the coolant flow path 18d can be controlled independently.

The plasma processing apparatus according to a modified example of an embodiment of the present invention includes: a stage 12 in which a first electrode 13 and a second electrode 14 that is provided around the first electrode 13 are formed separately, a substrate being placed above the first electrode 13, a focus ring 16 being provided above the second electrode 14; a first high-frequency power supply 21 that applies first high-frequency power LF used mainly for drawing an ion in a plasma to the first electrode 13 and the second electrode 14; and two cooling lines, which are provided in the first electrode 13 and the second electrode 14, respectively, and are used as independent coolant flow paths 18a and 18d.

Further, in the plasma processing apparatus 1 according to a modified example of an embodiment of the present invention, a part of a dielectric base 12a is formed by a conductive multi-contact element 100, and a first high-frequency power LF can be applied also to the second electrode 14 by applying the first high-frequency power LF from the first high-frequency power supply 21 to the first electrode 13.

Further, the plasma processing apparatus 1 according to a modified example of an embodiment of the present invention may include an upper electrode (gas shower head 40), and may apply high-frequency power HF from a third high-frequency power supply 22 that is used for mainly generating a plasma to any of the upper electrode, the first electrode 13, and the first and second electrodes 13 and 14.

The second electrode 14 may be made of a material whose heat conductivity is lower than that of the first electrode 13.

A vacuum space 120 may be formed inside of the second electrode 14.

A heat insulating material 110 may be included between the second electrode 14 and the dielectric base 12a.

As described above, a plasma processing apparatus according to an embodiment of the present invention have been described. The plasma processing apparatus is not limited to the above-described embodiment, and various variations and modifications can be made within the range of the present invention. Matters described in the embodiments may be combined within the non-conflicting range.

For example, the structure of the stage 12 of the present invention may be applied, not only to the parallel plate type plasma processing apparatus illustrated in FIG. 1, but also to other plasma processing apparatuses. The other plasma processing apparatuses may be a capacitively coupled plasma (CCP) apparatus, an inductively coupled plasma (ICP) processing apparatus, a plasma processing apparatus that uses a radial line slot antenna, a helicon wave plasma (HWP) apparatus, an electron cyclotron resonance plasma (ECR) apparatus, a surface wave plasma processing apparatus, etc.

In the present specification, a semiconductor wafer W has been described as a process target substrate. However, the process target substrate is not limited to the above, but may be various type of substrates used for an LCD (Liquid Crystal Display), an FPD (Flat Panel Display), etc., or may be a photo-mask, a CD substrate, a printed board, etc.

The present application is based on and claims the benefit of priority of Japanese Priority Application No. 2017-006245 filed on Jan. 17, 2017, the entire contents of which are hereby incorporated herein by reference.

What is claimed is:

1. A plasma processing apparatus that plasmatizes a gas that is supplied to inside of a chamber by using high-frequency power used for generating a plasma and applies plasma processing to a substrate, the plasma processing apparatus comprising:
a stage in which a first electrode and a second electrode are formed separately, the second electrode being provided around the first electrode, the substrate being placed above the first electrode, a focus ring being provided above the second electrode;
a first high-frequency power supply configured to apply to the first electrode first high-frequency power used for mainly drawing an ion in the plasma; and
a second high-frequency power supply, provided independently from the first high-frequency power supply, configured to apply to the second electrode second high-frequency power used for mainly drawing an ion in the plasma.

2. The plasma processing apparatus according to claim 1, further comprising: a control unit configured to control the first high-frequency power supply and the second high-frequency power supply, independently.

3. The plasma processing apparatus according to claim 2, wherein the
frequencies of the first high-frequency power and the second high-frequency power are equal to or less than 20 MHz, and
the control unit controls the second high-frequency power to be higher than the first high-frequency power according to a wear amount of the focus ring at the time of plasma processing.

4. The plasma processing apparatus according to claim 2, wherein the control unit controls the second high-frequency power to be lower than the first high-frequency power according to a wear amount of the focus ring at the time of cleaning processing.

5. The plasma processing apparatus according to claim 2, further comprising: a third high-frequency power supply configured to apply to the first electrode third high-frequency power, whose frequency is greater than 20 MHz, used for generating a plasma; and
a fourth high-frequency power supply, which is provided independently from the third high-frequency power supply, configured to apply to the second electrode fourth high-frequency power, whose frequency is greater than 20 MHz, used for generating a plasma, wherein
the control unit controls at least one of the third high-frequency power supply and the fourth high-frequency power supply, independently.

6. The plasma processing apparatus according to claim 2, wherein the control unit applies high-frequency power, whose frequency is greater than 20 MHz, used for generating the plasma to the first electrode, to the first electrode and the second electrode, or to an upper electrode that is provided to face the stage.

7. The plasma processing apparatus according to claim 2, further comprising:
a first DC power supply configured to apply a first DC current to the first electrode; and
a second DC power supply configured to apply a second DC current to the second electrode, wherein
the control unit controls at least one of the first DC power supply and the second DC power supply, independently.
